(19) United States
(12) Patent Application Publication
(10) Pub. No.: US 2017/0365490 A1
(43) Pub. Date: Dec. 21, 2017

(54) METHODS FOR POLYMER COEFFICIENT OF THERMAL EXPANSION (CTE) TUNING BY MICROWAVE CURING

(71) Applicant: APPLIED MATERIALS, INC., Santa Clara, CA (US)

(72) Inventors: YUEH SHENG OW, Singapore (SG); RUI WANG, Singapore (SG); TUCK FOONG KOH, Singapore (SG); XIN WANG, Singapore (SG)

(21) Appl. No.: 15/451,603

(22) Filed: Mar. 7, 2017

Related U.S. Application Data
(60) Provisional application No. 62/352,005, filed on Jun. 19, 2016.

(51) Int. Cl. H01L 21/56; H05B 6/70; H05B 6/64; H01L 21/3105; H01L 23/29; H01L 21/67; H05B 6/80; H05B 6/68

(52) U.S. Cl. CPC H01L 21/565; H05B 6/80; H05B 6/705; H05B 6/68; H01L 21/31058; H01L 23/293; H01L 21/67248; H01L 21/67115; H05B 6/645

(57) ABSTRACT

Methods of curing polyimide to tune the coefficient of thermal expansion are provided herein. In some embodiments, a method of curing a polymer layer on a substrate, includes: (a) applying a variable frequency microwave energy to the substrate to heat the polymer layer and the substrate to a first temperature; and (b) adjusting the variable frequency microwave energy to increase a temperature of the polymer layer and the substrate to a second temperature to cure the polymer layer.

### CROSS-REFERENCE TO RELATED APPLICATIONS

This application claims benefit of U.S. provisional patent application Ser. No. 62/352,005, filed Jun. 19, 2016, which is herein incorporated by reference in its entirety.

### FIELD

Embodiments of the present disclosure generally relate to curing polymers using microwave energy.

### BACKGROUND

Layers of various conductive and non-conductive polymeric materials are applied to semiconductor wafers during various stages of production. Polyimide is a polymer material that is frequently used in semiconductor manufacturing. Polyimide is often used as an insulating material for semiconductor wafers.

The coefficient of thermal expansion (CTE) is an important polymer property in polymer application in the semiconductor industry. For example, in fan-out wafer level packaging, there are often multiple layers of polyimide used. During thermal processes, the mismatch of polyimide CTE to other adjacent materials, such as epoxy or metals, can cause yield loss by increasing wafer warpage, pattern cracks and polymer/metal delamination.

Accordingly, the inventors have developed improved methods of curing polymers, such as polyimide, to tune the coefficient of thermal expansion.

### SUMMARY

Methods of curing polyimide to tune the coefficient of thermal expansion are provided herein. In some embodiments, a method of curing a polymer layer on a substrate, includes: (a) applying variable frequency microwave energy to the substrate to heat the polymer layer and the substrate to a first temperature; and (b) adjusting the variable frequency microwave energy to increase a temperature of the polymer layer and the substrate to a second temperature to cure the polymer layer.

In some embodiments, a method of curing a polymer layer on a substrate, includes: (a) applying variable frequency microwave energy to the substrate to heat the polymer layer and the substrate to a first temperature of about 170 to about 200 degrees Celsius for a first period of time; and (b) adjusting the variable frequency microwave energy to increase a temperature of the polymer layer and the substrate to a second temperature of about 300 to about 400 degrees Celsius for a second period of time to cure the polymer layer, wherein (a)-(b) are performed within a microwave processing chamber under vacuum.

In some embodiments, a method of curing a polyimide layer on a substrate, includes: (a) applying variable frequency microwave energy at microwave frequencies ranging from about 5.85 GHz to about 6.65 GHz, and at a sweep rate of about 0.25 microseconds per frequency, to the substrate to heat the polyimide layer and the substrate to a first temperature of about 170 to about 200 degrees Celsius, wherein the polyimide layer and the substrate are heated from about 25 degrees Celsius to the first temperature at a first rate of about 0.01 degrees Celsius to about 4 degrees Celsius per second, and wherein the polyimide layer is maintained at the first temperature for a first period of time of about 10 minutes to about 60 minutes; and (b) adjusting the variable frequency microwave energy to increase a temperature of the polyimide layer and the substrate to a second temperature of about 300 to about 400 degrees Celsius to cure the polyimide layer, wherein the polyimide layer and the substrate are heated from the first temperature to the second temperature at a second rate of about 0.01 degrees Celsius to about 4 degrees Celsius per second, and wherein the polyimide layer is maintained at the second temperature for a second period of time of about 5 to about 60 minutes, wherein (a)-(b) are performed within a microwave processing chamber under vacuum.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. The appended drawings illustrate only typical embodiments of the disclosure and are therefore not to be considered limiting of scope, for the disclosure may admit to other equally effective embodiments.

FIG. 1 depicts a flow chart for a method of curing a polymer layer on a semiconductor substrate in accordance with some embodiments of the present disclosure.

FIG. 2 depicts a schematic side view of a process chamber for a polymer microwave curing process in accordance with some embodiments of the present disclosure.

FIG. 3 depicts a table of temperature profiles for a polymer microwave curing process in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Improved methods of curing polyimide to tune the coefficient of thermal expansion are disclosed herein. Embodiments of the current disclosure advantageously have the capability to tune the coefficient of thermal expansion (CTE) of a polymer, such as polyimide, over a wide range to match or substantially match the CTE of adjacent materials. The ability to tune the CTE of polyimide broadens the process margin for any following thermal process, reduces crack and stress in the substrate, and improves the wafer yield and reliability. Embodiments of the current disclosure further advantageously improve the imidization reaction efficiency of polyimide, improve polyimide molecule alignment, reduce the stress in the polyimide film after curing, and drive out volatile residue from the curing process. Embodiments of the current disclosure may advantageously be used in semiconductor manufacturing applications, such as fan out wafer level packaging applications.

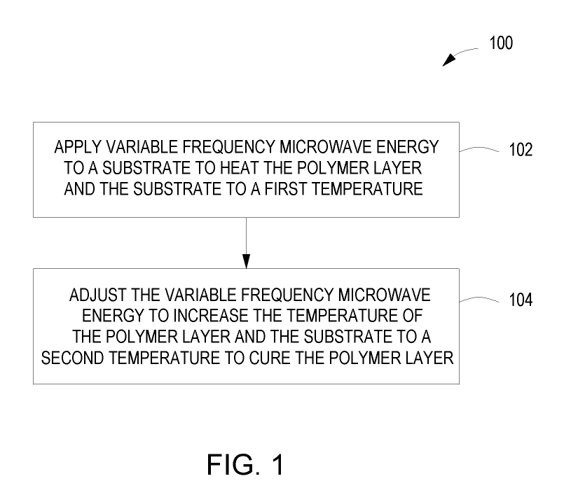

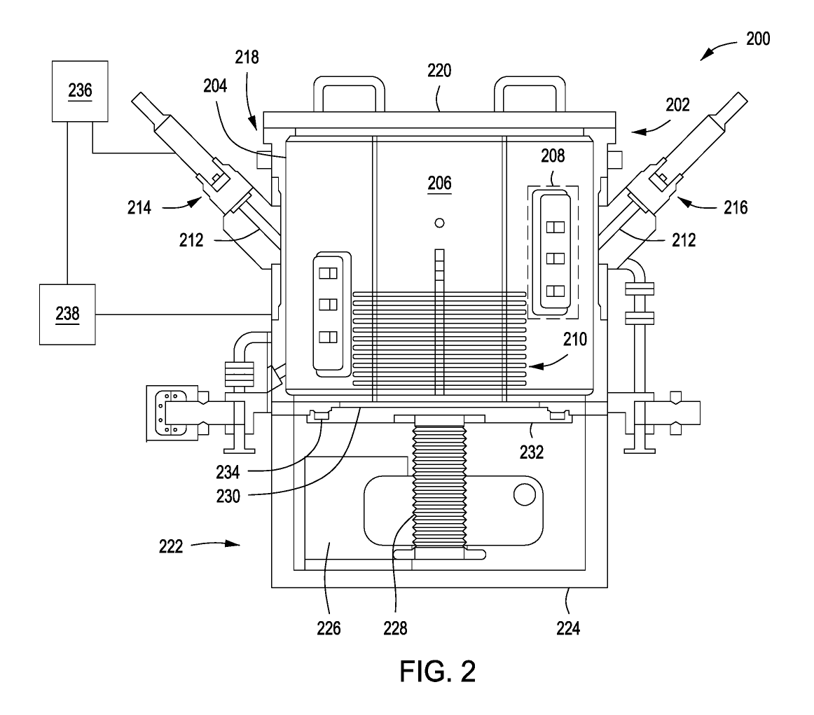

FIG. 1 is a flow diagram of a method 100 of curing a polymer layer on a semiconductor substrate in accordance with some embodiments of the present disclosure. A semiconductor substrate having a polymer layer is placed into a suitable microwave processing chamber such as discussed below with respect to FIG. 2. In some embodiments, the polymer layer is polyimide. Polyimide is frequently used in semiconductor manufacturing, for example as an insulating material for semiconductor wafers.

The method 100 is performed at vacuum (e.g., about 50 to about 1e-6 Torr, or below). The inventors have observed that performing the method 100 at vacuum helps to drive out volatile precursor (e.g. gases and vapors) residue that forms during the curing process. Conventional non-microwave curing occurs at high pressure (e.g., about 1 atmosphere, or about 760 Torr) and thus uses high temperature to drive out residues.

The method 100 begins at 102, where a variable frequency microwave energy is applied to the substrate (e.g., a semiconductor substrate) to heat the polymer layer (e.g., a polyimide layer) and substrate to a first temperature. The polymer layer is heated from about room temperature (e.g., about 25 degrees Celsius) to a first temperature of about 170 to about 200 degrees Celsius. The polymer layer is heated to remove any residual solvents in the polymer layer. In some embodiments, the polymer layer is heated from room temperature to the first temperature at a first rate of about 0.01 degrees Celsius to about 4 degrees Celsius per second, such as about 2 degrees Celsius per second. The polymer layer is maintained at the first temperature for a first period of time sufficient to remove any residual solvents. In some embodiments, the first period of time is about 10 minutes to about 60 minutes. Furthermore, the polymer layer is maintained at the first temperature for the first period of time selected to tune, or control, the CTE of the polymer layer. Without wishing to be bound by theory, the inventors believe that maintaining the polymer layer at the first temperature for the first period of time allows some molecular alignment, or hardening, of the polymer layer to occur. When the polymer layer is heated to a higher temperature, such as the second temperature discussed below, many of the molecules are fixed in an aligned position, resulting in a lower CTE as a result of less free space between molecules.

The temperature of the polymer layer and the semiconductor substrate is controlled by the amount of microwave energy applied to the polymer layer and the semiconductor substrate. The greater the amount of microwave energy supplied the greater the temperature of the polymer layer and the semiconductor substrate. In some embodiments, the semiconductor substrate is subjected to microwave energy from a broad C-band source with microwave frequencies ranging from about 5.85 GHz to about 6.65 GHz. In some embodiments, the sweep rate is about 0.25 microseconds per frequency across 4096 frequencies in the C-band. The use of variable frequency and a fast sweeping prevents standing wave formation and charge accumulation and the need for a rotating thermal load. The use of variable frequency also allows for uniform cross substrate temperature distribution. The application of microwave energy also results in the substrate (e.g. a silicon wafer) becoming a direct heater itself.

Next, at 104, the variable frequency microwave energy is adjusted to increase the temperature of the polymer layer and the semiconductor substrate to a second temperature, greater than the first temperature, to cure the polymer layer. The temperature of the polymer layer and the semiconductor substrate is increased to a second temperature of about 300 to about 400 degrees Celsius. In some embodiments, the polymer layer is heated from the first temperature to the second temperature at a second rate of about 0.01 degrees Celsius per second to about 4 degrees Celsius per second, such as about 2 degrees Celsius per second. The polymer layer is maintained at the second temperature for a second period of time of about 5 minutes to about 60 minutes.

Imidization is the major chemical reaction that occurs during polymer curing. The inventors have observed that, unlike convention non-microwave curing methods, microwave curing methods helps imidization by delivering energy directly to the polarizable dipoles on polyimide molecules, which causes functional group rotation at reaction sites. In addition, microwave curing provides for a low thermal budget that can decrease the stress built in the cured polymer layer. Microwave curing also improves polymer molecule alignment. Microwave power provides additional molecule vibration resulting in the molecule tending to arrange in a lower energy state (i.e., an ordered layer). Improving the polymer molecule alignment lowers the CTE of the polymer layer. The inventors have discovered that controlling the above-described parameters facilitates control over the amount of polymer molecule alignment thus advantageously facilitating control, or tuning, of the CTE of the polymer layer.

In some embodiments, following 104, the variable frequency microwave energy can optionally be adjusted to decrease the temperature of the polymer layer and the semiconductor substrate to a third temperature that is less than the second temperature. In some embodiments, the third temperature is about 250 to about 350 degrees Celsius. In some embodiments, the temperature of the polymer layer and the semiconductor substrate is decreased at a third rate of about 0.01 degrees Celsius per second to about 4 degrees Celsius per second, such as about 2 degrees Celsius per second. The polymer layer is maintained at the third temperature for a third period of time of about 30 minutes, although other time periods can be used.

The inventors have observed that by applying microwave energy to cure a polymer layer and by adjusting the temperature profile (e.g., the temperature of the polymer layer, the temperature ramp rate, and the soak time), the coefficient of thermal expansion (CTE) of the polymer layer can be tuned over a wide range, for example from about 21 to about 58.

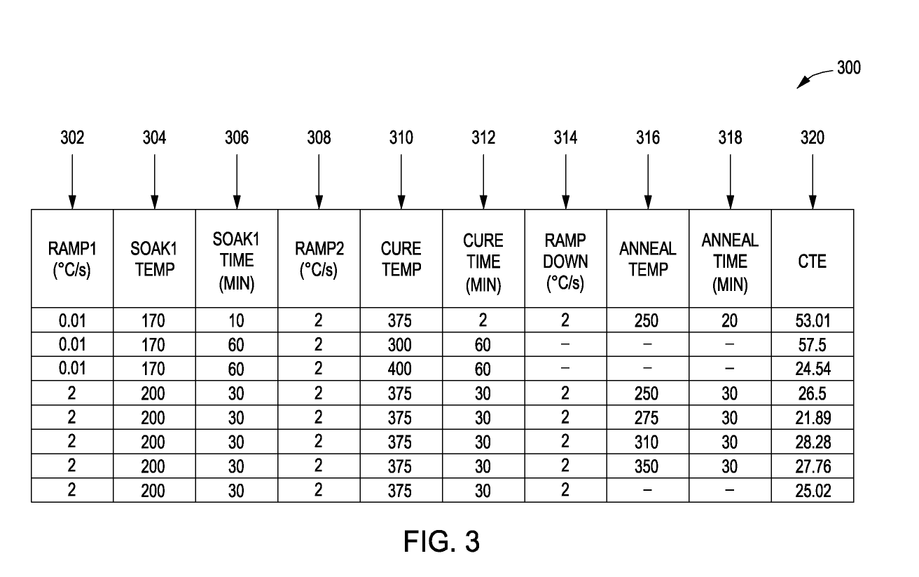

FIG. 3 depicts a table 300 of several exemplary temperature profiles that provide a polyimide CTE within over the wide range mentioned above. FIG. 300 depicts a column 302 showing a temperature ramp rate from room temperature to a first temperature shown in column 304. A column 306 shows a first amount of time that the semiconductor substrate is held at the first temperature. FIG. 300 further depicts a column 308 showing a temperature ramp rate from the first temperature to a second temperature shown in column 310. A column 312 shows a second amount of time that the semiconductor substrate is held at the second temperature. A column 314 shows a temperature ramp rate from the second temperature to a third temperature shown in column 316. A column 318 shows a third amount of time that the semiconductor substrate is held at the third temperature. A column 320 shows the CTE value from the exemplary temperature profile used in each row.

FIG. 2 depicts a suitable microwave processing chamber 200 for performing the method 100 described above. The microwave processing chamber 200 comprises an octagonal body 202. The octagonal body 202 has a thickness sufficient for use as a microwave chamber. The octagonal body 202 comprises an octagonal cavity 204 having a first volume 206. One or more substrates 210, for example semiconductor wafers or other substrates having materials to be microwave cured may be disposed within the octagonal cavity 204 during curing operations. A top 218 of the octagonal body 202 has a lid 220 to seal the first volume 206.

The octagonal body 202 is suitable for receiving variable frequency microwave energy. The octagonal body 202 further comprises a plurality of openings 208 fluidly coupled to the first volume 206. The plurality of openings 208 facilitates delivery of the microwave energy to the first volume 206. The plurality of openings 208 are coupled to a suitable variable frequency microwave source 238. In some embodiments, each opening 208 may be rectangular. In some embodiments, each opening 208 may include angled sidewalls that enlarge the opening on a side of the opening facing the first volume 206. In some embodiments, the openings 208 are staggered, or spaced apart, along the octagonal body 202. In some embodiments, the octagonal body 202 comprises four openings 208, wherein two of the four openings 208 are disposed along the octagonal body 202 opposite to each other and the other two openings 208 are disposed along the octagonal body 202 opposite to each other but not opposite to the first two openings 208. In some embodiments, each opening 208 is a singular opening along the octagonal body 202. In some embodiment, each opening 208 comprises multiple openings along the octagonal body 202.

The octagonal body 202 comprises one or more ports 212 fluidly coupled to the first volume 206. One or more temperature sensors 214, 216 are disposed within the ports 212 to measure a temperature of the one or more semiconductor substrates within the first volume 206. The temperature sensors 214, 216 are coupled to a PID controller 236, which is coupled to the variable frequency microwave source 238 to control the amount of microwave power supplied to the microwave processing chamber 200. An exhaust port (not shown) may be coupled to the octagonal body 202 and fluidly coupled to the first volume 206 to create a vacuum within the first volume 206 suitable for performing method 100.

The microwave processing chamber 200 further comprises a substrate transfer apparatus 222 having a lower chamber 224. The lower chamber 224 is disposed below the octagonal body 202 and is coupled to the octagonal body 202. The lower chamber 224 comprises a second volume 226 holding one or more substrates 210 (such as semiconductor substrates). The second volume 226 is fluidly coupled to the first volume 206. In some embodiments, the one or more substrates 210 are aligned parallel to each other in a stacked configuration.

A lift mechanism 228 is provided to lift the one or more substrates 210 from the lower chamber 224 into the first volume 206 of the octagonal cavity 204. The lift mechanism 228 may be any suitable lift mechanism, such as an actuator, motor, or the like. In some embodiments, the lift mechanism 228 is coupled to a substrate support 230 that may be disposed in the lower chamber 224 or moved into the first volume 206 of the octagonal cavity 204.

Once the one or more substrates 210 are raised into the first volume 206 of the octagonal cavity 204, a lower plate 232 coupled to the substrate support 230 seals a second volume 226 of the lower chamber 224 from the first volume 206 of the octagonal cavity 204 to prevent escape of microwaves and maintain a predetermined pressure in the first volume 206. The lower plate 232 butts up against, or mates with, an adapter 234 such that there is no gap, or a minimal gap, between the lower plate 232 and the adapter 234, thus sealing the first volume 206. The adapter 234 is coupled to an inner surface of the lower chamber 224.

While the foregoing is directed to embodiments of the present disclosure, other and further embodiments of the disclosure may be devised without departing from the basic scope thereof.

1. A method of curing a polymer layer on a substrate, comprising:
(a) applying a variable frequency microwave energy to the substrate to heat the polymer layer and the substrate to a first temperature; and
(b) adjusting the variable frequency microwave energy to increase a temperature of the polymer layer and the substrate to a second temperature to cure the polymer layer.

2. The method of claim 1, wherein the polymer layer is polyimide.

3. The method of claim 1, wherein the first temperature is about 170 to about 200 degrees Celsius.

4. The method of claim 3, wherein the polymer layer and the substrate are heated from about 25 degrees Celsius to the first temperature at a first rate of about 0.01 degrees Celsius to about 4 degrees Celsius per second.

5. The method of claim 1, wherein the polymer layer is maintained at the first temperature for a first period of time of about 10 minutes to about 60 minutes.

6. The method of claim 1, wherein the variable frequency microwave energy is provided at microwave frequencies ranging from about 5.85 GHz to about 6.65 GHz.

7. The method of claim 6, wherein the variable frequency microwave energy is provided at a sweep rate of about 0.25 microseconds per frequency.

8. The method of claim 1, wherein the second temperature is about 300 to about 400 degrees Celsius.

9. The method of claim 8, wherein the polymer layer and the substrate are heated from the first temperature to the second temperature at a second rate of about 0.01 degrees Celsius per second to about 4 degrees Celsius per second.

10. The method of claim 1, wherein the polymer layer is maintained at the second temperature for a second period of time of about 5 to about 60 minutes.

11. The method of claim 1, further comprising adjusting the variable frequency microwave energy to decrease the temperature of the polymer layer and the substrate to a third temperature less than the second temperature.

12. The method of claim 11, wherein the third temperature is about 250 to about 350 degrees Celsius.

13. The method of claim 11, wherein the temperature of the polymer layer and the substrate is decreased from the second temperature to the third temperature at a third rate of about 0.01 degrees Celsius per second to about 4 degrees Celsius per second.

14. The method of claim 11, wherein the polymer layer is maintained at the third temperature for a third period of time of about 30 minutes.

15. The method of claim 1, wherein (a)-(b) are performed within a microwave processing chamber under vacuum.

16. A method of curing a polymer layer on a substrate, comprising:
(a) applying a variable frequency microwave energy to the substrate to heat the polymer layer and the substrate to a first temperature of about 170 to about 200 degrees Celsius for a first period of time; and
(b) adjusting the variable frequency microwave energy to increase a temperature of the polymer layer and the substrate to a second temperature of about 300 to about 400 degrees Celsius for a second period of time to cure the polymer layer, wherein (a)-(b) are performed within a microwave processing chamber under vacuum.

17. The method of claim 16, wherein the first period of time is about 10 minutes to about 60 minutes.

18. The method of claim 16, wherein the second period of time is about 5 to about 60 minutes.

19. A method of curing a polyimide layer on a substrate, comprising:
(a) applying a variable frequency microwave energy at microwave frequencies ranging from about 5.85 GHz to about 6.65 GHz, and at a sweep rate of about 0.25 microseconds per frequency, to the substrate to heat the polyimide layer and the substrate to a first temperature of about 170 to about 200 degrees Celsius, wherein the polyimide layer and the substrate are heated from about 25 degrees Celsius to the first temperature at a first rate of about 0.01 degrees Celsius to about 4 degrees Celsius per second, and wherein the polyimide layer is maintained at the first temperature for a first period of time of about 10 minutes to about 60 minutes; and
(b) adjusting the variable frequency microwave energy to increase a temperature of the polyimide layer and the substrate to a second temperature of about 300 to about 400 degrees Celsius to cure the polyimide layer, wherein the polyimide layer and the substrate are heated from the first temperature to the second temperature at a second rate of about 0.01 degrees Celsius to about 4 degrees Celsius per second, and wherein the polyimide layer is maintained at the second temperature for a second period of time of about 5 to about 60 minutes, and wherein (a)-(b) are performed within a microwave processing chamber under vacuum.

20. The method of claim 19, further comprising:
(c) adjusting the variable frequency microwave energy to decrease the temperature of the polyimide layer and the substrate to a third temperature less than the second temperature, wherein the third temperature is about 250 to about 350 degrees Celsius, and wherein the temperature of the polyimide layer and the substrate is decreased from the second temperature to the third temperature at a third rate of about 0.01 degrees Celsius to about 4 degrees Celsius per second, and wherein the polyimide layer is maintained at the third temperature for a third period of time of about 30 minutes, and wherein (c) is performed within the microwave processing chamber under vacuum.
